(19) United States
(12) Patent Application Publication
(10) Pub. No.: US 2024/0355987 A1
(43) Pub. Date: Oct. 24, 2024

(54) WIRING SUBSTRATE, LIGHT-EMITTING DEVICE, AND MANUFACTURING METHODS THEREOF

(71) Applicant: NICHIA CORPORATION, Anan-shi (JP)

(72) Inventors: Masaaki KATSUMATA, Anan-shi (JP); Eiko MINATO, Anan-shi (JP); Takashi KAWAMATA, Tokushima-shi (JP); Atsushi HOSOKAWA, Tokushima-shi (JP)

(73) Assignee: NICHIA CORPORATION, Anan-shi (JP)

(21) Appl. No.: 18/637,994

(22) Filed: Apr. 17, 2024

(30) Foreign Application Priority Data
Apr. 18, 2023 (JP) 2023-067931

(51) Int. Cl. H01L 33/62; H01L 25/075; H01L 33/20

(52) U.S. Cl. CPC H01L 33/62; H01L 25/0753; H01L 33/20; H01L 2933/0066

(57) ABSTRACT

A wiring substrate includes a base body, a metal member, and an insulating member. The base body is insulating and has a first surface and a second surface on an opposite side to the first surface. The base body includes a groove portion provided on a second surface side, and a through hole connecting the first surface and a bottom surface of the groove portion. The metal member is disposed in the groove portion on the bottom surface side of the groove portion and in the through hole away from an opening of the groove portion. The insulating member is disposed so as to close the opening of the groove portion.

### CROSS-REFERENCE TO RELATED APPLICATIONS

The present application claims priority under 35 U.S.C. § 119 to Japanese Patent Application No. 2023-067931, filed Apr. 18, 2023, the contents of which is hereby incorporated by reference in its entirety.

### 1. TECHNICAL FIELD

The present disclosure relates to a wiring substrate, a light-emitting device, and manufacturing methods of the wiring substrate and the light-emitting device.

### 2. DESCRIPTION OF RELATED ART

Conventionally, in a ceramic substrate excellent in high thermal conductivity, such as a Si₃N₄ substrate, an active metal brazing material is used for a via material or a wiring line. See, for example, Japanese Patent No. 5693940 and Japanese Patent No. 6541530).

### SUMMARY

Embodiments of the present disclosure can provide a wiring substrate that allows improving a thermal bonding property with a heat dissipating plate or the like, a light-emitting device using the wiring substrate, and manufacturing methods of the wiring substrate and the light-emitting device.

According to one aspect of the present disclosure, a wiring substrate includes a base body, a metal member, and an insulating member. The base body is insulating and has a first surface and a second surface on an opposite side to the first surface. The base body includes a groove portion provided on a second surface side, and a through hole connecting the first surface and a bottom surface of the groove portion. The metal member is disposed in the groove portion on the bottom surface side of the groove portion and in the through hole away from an opening of the groove portion. The insulating member is disposed so as to close the opening of the groove portion.

According to another aspect of the present disclosure, a light-emitting device includes the wiring substrate disclosed in the embodiment(s) and a light-emitting element disposed on a first surface side of the wiring substrate. The light-emitting element includes an element electrode. The metal member of the wiring substrate is electrically connected to the element electrode.

According to another aspect of the present disclosure, a manufacturing method of a wiring substrate includes: preparing a base body having a first surface and a second surface on an opposite side to the first surface, the base body including a through hole and a groove portion, the through hole extending through so as to connect the first surface and the second surface, the groove portion being connected to the through hole and located at a second surface side; disposing a conductive paste in the groove portion and the through hole, the conductive paste containing at least a metal powder, an active metal powder, and an organic solvent; obtaining a metal member by firing the conductive paste; and disposing an insulating member so as to close an opening of the groove portion.

According to a further aspect of the present disclosure, a manufacturing method of a light-emitting device includes providing the wiring substrate manufactured by the manufacturing method of the wiring substrate disclosed in the embodiment(s), and disposing a light-emitting element on the wiring substrate. The light-emitting element includes an element electrode. In the disposing the light-emitting element, the metal member of the wiring substrate and the element electrode are electrically connected.

According to the embodiments of the present disclosure, a wiring substrate that allows improving a thermal bonding property with a heat dissipating plate or the like, a light-emitting device using the wiring substrate, and manufacturing methods of the wiring substrate and the light-emitting device can be provided.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1A is a schematic plan view of an example of a wiring substrate according to an embodiment of the present disclosure.

FIG. 1B is a schematic bottom view of an example of the wiring substrate according to the embodiment.

FIG. 2A is a cross-sectional view taken along a line IIA-IIA in FIG. 1A.

FIG. 2B is a cross-sectional view taken along a line IIB-IIB in FIG. 1A.

FIG. 2C is an enlarged schematic cross-sectional view of an example of an interface between a metal member and a base body in the wiring substrate according to the embodiment.

FIG. 3 is a flowchart for an example of a manufacturing method of the wiring substrate according to the embodiment.

FIG. 4A is a schematic cross-sectional view of an example of a base body before being processed in an example of the manufacturing method of the wiring substrate according to the embodiment.

FIG. 4B is a schematic cross-sectional view of an example of the base body in which groove portions have been formed in an example of the manufacturing method of the wiring substrate according to the embodiment.

FIG. 4C is a schematic cross-sectional view of an example of the base body in which a through hole has been formed in an example of the manufacturing method of the wiring substrate according to the embodiment.

FIG. 4D is a schematic cross-sectional view of an example of the base body on which a conductive paste has been disposed in an example of the manufacturing method of the wiring substrate according to the embodiment.

FIG. 4E is a schematic cross-sectional view of an example of the base body in which the conductive paste has been fired in an example of the manufacturing method of the wiring substrate according to the embodiment.

FIG. 4F is a schematic cross-sectional view of an example of the base body in which openings of the groove portions have been formed on curved surfaces in an example of the manufacturing method of the wiring substrate according to the embodiment.

FIG. 4G is a schematic cross-sectional view of an example of the base body in which insulating members have been disposed in the groove portions in an example of the manufacturing method of the wiring substrate according to the embodiment.

FIG. 4H is a schematic cross-sectional view of an example of the base body in which the insulating members have been polished in an example of the manufacturing method of the wiring substrate according to the embodiment.

FIG. 5A is a schematic cross-sectional view of a modified example of the wiring substrate.

FIG. 5B is a schematic cross-sectional view of an example of the base body in which the conductive paste has been fired in a manufacturing method of the modified example of the wiring substrate.

FIG. 6 is a schematic cross-sectional view of an application example of the wiring substrate.

FIG. 7 is a schematic plan view of an example of a light-emitting device according to the embodiment.

FIG. 8 is a cross-sectional view taken along a line VIII-VIII in FIG. 7.

FIG. 9 is a flowchart of an example of a manufacturing method of the light-emitting device according to the embodiment.

FIG. 10A is a schematic cross-sectional view of an example of the prepared wiring substrate in an example of the manufacturing method of the light-emitting device according to the embodiment.

FIG. 10B is a schematic cross-sectional view of an example of a state in which a light-emitting element has been disposed on the wiring substrate in an example of the manufacturing method of the light-emitting device according to the embodiment.

FIG. 10C is a schematic cross-sectional view of an example of a state in which a heat dissipating plate has been bonded to the wiring substrate in an example of the manufacturing method of the light-emitting device according to the embodiment.

### DETAILED DESCRIPTION

### Description of Embodiments

Embodiments according to the present disclosure will be described below with reference to the drawings. However, the embodiments described below are merely intended to embody the technical concept according to the present disclosure, and the invention is not limited to the following description unless otherwise specified. The content described in one embodiment can also be applied to another embodiment or a modified example. The drawings are diagrams that schematically illustrate the embodiments. In order to provide clarity in the description, scales, intervals, positional relationships, and the like of members may be exaggerated, or some of the members may be omitted in the drawings. Directions illustrated in the drawings indicate relative positions between constitution components and are not intended to indicate absolute positions. Members having the same names and reference signs, as a rule, represent the same members or members of the same quality, and detailed description thereof is omitted as appropriate. In the embodiments, “covering” includes not only a case of covering by direct contact but also a case of indirectly covering, for example, via another member. Furthermore, “disposing” includes not only a case of disposing by direct contact but also a case of indirectly disposing, for example, via another member.

### Wiring Substrate

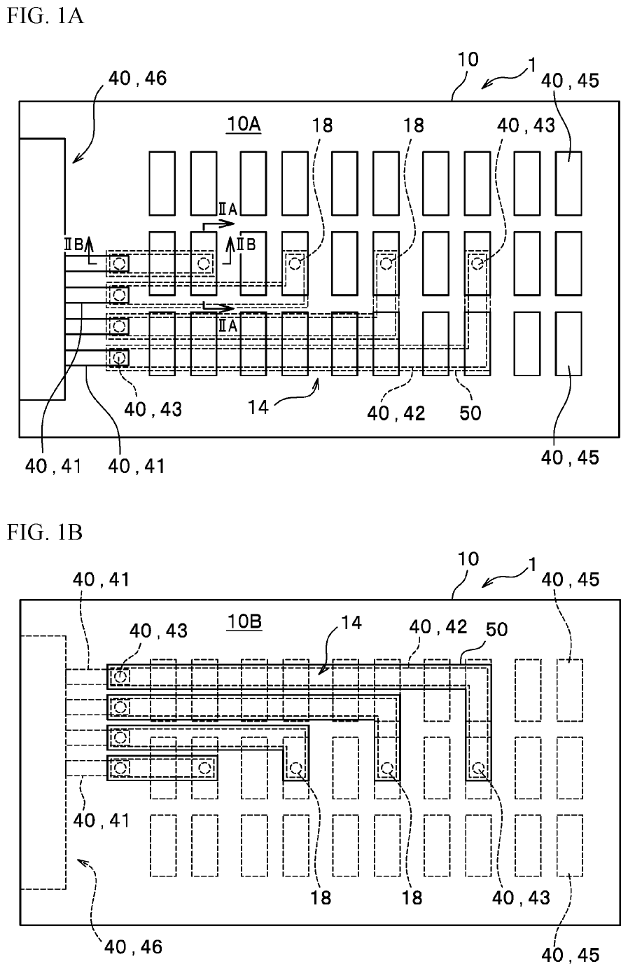

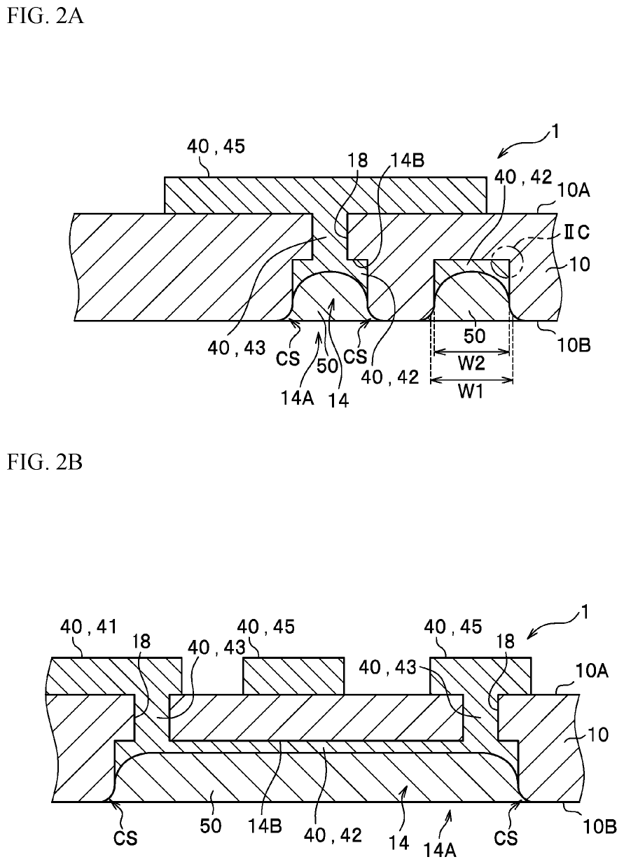

A wiring substrate 1 according to the embodiment will be described with reference to FIGS. 1A to 2C. FIG. 1A is a schematic plan view of an example of the wiring substrate 1. FIG. 1B is a schematic bottom view of an example of the wiring substrate 1. FIG. 2A is a cross-sectional view taken along a line IIA-IIA in FIG. 1A. FIG. 2B is a cross-sectional view taken along a line IIB-IIB in FIG. 1A. FIG. 2C is an enlarged schematic cross-sectional view of an example of an interface between a metal member and a base body.

The wiring substrate 1 includes a base body 10, a metal member 40, and an insulating member 50. The base body 10 is insulating and has a first surface 10A and a second surface 10B as an opposite side to the first surface 10A. The base body 10 includes a groove portion 14 provided on the second surface 10B side, and a through hole 18 connecting the first surface 10A and a bottom surface 14B of the groove portion 14. The metal member 40 is disposed in the groove portion on the bottom surface 14B side of the groove portion 14 and in the through hole 18 away from an opening 14A of the groove portion 14. The insulating member 50 is disposed so as to close the opening 14A of the groove portion 14. Each component of the wiring substrate 1 is described below.

### Base Body

The base body 10 is a plate-shaped member serving as a base of the wiring substrate 1. The base body 10 has the first surface 10A and the second surface 10B as an opposite side to the first surface 10A, and includes the groove portions 14 provided on the second surface 10B and the through holes 18 connecting the bottom surfaces 14B of the groove portions 14 and the first surface 10A. The shape of the base body 10 in a plan view is, for example, a rectangular shape, and is not particularly limited. The thickness of the base body 10 can be, for example, in a range from 0.2 mm to 2 mm, and preferably in a range from 0.4 mm to 1.5 mm.

It is preferable that the base body 10 be insulating and have an excellent heat dissipating property. The material of the base body 10 can include or be a ceramic, and is preferably a fired ceramic. In the wiring substrate 1, by the base body 10 being made of a fired ceramic, a processing accuracy of the groove portion 14 and the through hole 18 can be improved. The base body 10 can be a ceramic containing at least one of silicon nitride, aluminum nitride, boron nitride, magnesium oxide, and aluminum oxide, and preferably contains silicon nitride or aluminum nitride. Note that the base body 10 is preferably made of a nitride ceramic, such as silicon nitride, aluminum nitride, or boron nitride, or a combination thereof, but may be made of an oxide ceramic, such as aluminum oxide, silicon oxide, calcium oxide, or magnesium oxide, or a combination thereof. Also, the base body 10 may be made of beryllium oxide, silicon carbide, mullite, borosilicate glass, or the like, or a combination thereof.

### Groove Portion

The groove portion 14 is a groove provided on the second surface 10B, is recessed from the second surface 10B, and in which the metal member 40 is embedded. As described later, the metal member 40 embedded in the groove portion 14 constitutes an embedded wiring line 42, and one embedded wiring line 42 is disposed in one groove portion 14.

The depth of the bottom surface 14B of the groove portion 14 from the second surface 10B can be in a range from ⅛ to ⅞, preferably in a range from ¼ to ¾, and particularly preferably in a range from ⅜ to ⅝ with respect to the thickness of the base body 10. The depth of the bottom surface 14B of the groove portion 14 from the second surface 10B can be in a range from 30 μm to 80 μm, and preferably in a range from 50 μm to 60 μm. In the wiring substrate 1, by setting the above-described depth as 30 μm or more, the embedded metal member 40 and the second surface 10B can be separated from each other, and by setting the above-described depth as 80 μm or less, the strength of the base body 10 at the position of the bottom surface 14B can be maintained. The depth of the groove portion 14 is defined as the distance between the deepest position of the bottom surface 14B and the second surface 10B in the widthwise cross section. The width direction of the groove portion 14 is a horizontal direction in the plate-shaped base body 10 and is a direction perpendicular to the extending direction of the embedded wiring line 42.

Here, description will be made on the assumption that the bottom surface 14B is a flat surface, but in the case in which the through hole 18 is formed, description will be made on the assumption that a portion excluding the through hole 18 portion is a flat surface. However, the bottom surface 14B may be a curved surface instead of a flat surface. For example, the width W2 of the bottom surface 14B can be in a range from 15 μm to 500 μm. The width W2 of the bottom surface 14B refers to the width at the bottom surface 14B. However, the bottom surface 14B might be rough due to processing or the like, or the bottom surface 14B might be a curved surface, and the width of the groove portion 14 may be a length measured at a position away from the bottom surface 14B by a distance approximately in a range from 5 μm to 10 μm, or at a position away from the second surface 10B in the depth direction of the groove portion 14 by half the depth.

The groove portion 14 is continuous with the second surface 10B via a curved surface CS widening toward the opening 14A side. The curved surface CS can have an arc shape with a radius, for example, in a range from 0.1 μm to 20 μm, and preferably in a range from 0.5 μm to 10 μm in the widthwise cross section. The width W1 of the opening 14A of the groove portion 14 is wider than the width W2 of the bottom surface 14B. The width W1 of the opening 14A refers to the width at the second surface 10B. However, the bottom surface 14B might be rough due to processing or the like, or the bottom surface 14B might be a curved surface, and the width of the groove portion 14 may be a length measured at a position away from the second surface 10B in the depth direction of the groove portion 14 by 1/10 of the depth.

### Through Hole

The through hole 18 is a hole that connects the bottom surface 14B of the groove portion 14 of the second surface 10B and the first surface 10A. Here, the through hole 18 has a circular shape in a plan view, and has the same diameter from the bottom surface 14B to the first surface 10A. The diameter of the through hole 18 can be in a range from, for example, 50 μm to 500 μm, and preferably in a range from 100 μm to 300 μm. The diameter of the through hole 18 may be large on the first surface 10A side and small on the bottom surface 14B side to form a tapered shape, or vice versa. The shape of the through hole 18 in a plan view need not be circular, and may be, for example, polygonal including rectangular or elliptical.

### Metal Member

The metal member 40 is a member serving as an electrode material or a wiring material in the wiring substrate 1. The metal member 40 is disposed on the bottom surface 14B side of the groove portion 14 and in the through hole 18 away from the opening 14A of the groove portion 14.

The metal member 40 includes a pad portion 45 to which a circuit component, such as an electronic component, is connected, a terminal portion 46 to which an external wiring line is connected, and at least two wiring layers that connect between the pad portions 45 and between the pad portion 45 and the terminal portion 46. One of the two wiring layers is the embedded wiring line 42 embedded in the wiring substrate 1, and the other is an exposed wiring line 41 exposed from the wiring substrate 1. The exposed wiring line 41 and the embedded wiring line 42 are connected by a via wiring line 43 disposed in the through hole 18. The pad portion 45 and the terminal portion 46 are electrically connected to the metal member 40 disposed in the through hole 18. Note that, in the drawings, description of the exposed wiring line 41 is omitted except in some of the drawings. Also, the terminal portions 46 are collectively disposed in a part of a region, and description of individual terminals, such as a power source line and a signal line, is omitted.

Here, the pad portion 45, the terminal portion 46, and the exposed wiring line 41 are disposed having substantially uniform thicknesses on the first surface 10A of the wiring substrate 1. The thicknesses of the pad portion 45, the terminal portion 46, and the exposed wiring line 41 from the first surface 10A can be, for example, in a range from 5 μm to 100 μm, and preferably in a range from 10 μm to 50 μm.

The embedded wiring line 42 is disposed on the bottom surface 14B side of the groove portion 14. The metal member 40 disposed in the groove portion 14 has a curved surface at least at an interface with the insulating member 50. Here, the embedded wiring line 42 has a thickness from the bottom surface 14B that becomes thinner on the widthwise center side of the groove portion 14. The thickness of the embedded wiring line 42 from the bottom surface 14B at the widthwise center of the groove portion 14 can be, for example, in a range from 1 μm to 200 μm, and preferably in a range from 5 μm to 100 μm.

The via wiring line 43 is disposed so as to fill the through hole 18. Here, the via wiring line 43 has a cylindrical shape. The diameter of the via wiring line 43 can be, for example, in a range from 50 μm to 500 μm, and is preferably in a range from 100 μm to 300 μm.

The shape of the pad portion 45 in a plan view is, for example, a rectangular shape. In some of the pad portions 45, the through hole 18 is disposed at the center of each pad portion 45 in a plan view, and is connected to the embedded wiring line 42 via the via wiring line 43. The embedded wiring line 42 is connected to the exposed wiring line 41 via another via wiring line 43, and is connected to the terminal portion 46 from the exposed wiring line 41.

The metal member 40 contains a metal as a main component and contains at least one of Cu, Cr, Ni, Ag, Al, Zn, Sn, and an Ag—Cu alloy. The metal member 40 preferably further contains an active metal element, such as Ti, Ce, Zr, and Mg.

The metal member 40 preferably includes a metal compound layer 60 at an interface with the base body 10, and the metal member 40 is preferably disposed on the base body 10 via the metal compound layer 60. That is, the pad portion 45, the terminal portion 46, the exposed wiring line 41, the embedded wiring line 42, and the via wiring line 43 are preferably disposed on the base body 10 via the metal compound layer 60. By the metal member 40 including the metal compound layer 60 at the interface with the base body 10, the bonding between the metal member 40 and the base body 10 can be strengthened.

As exemplified in FIG. 2C, the metal compound layer 60 is a layer containing a large amount of a compound 61 of the active metal element contained in the metal member 40 and a nonmetallic inorganic element contained in the base body 10, such as N and O. The compound 61 is, for example, TiN or TiO₂. Although illustration of the metal compound layer 60 is omitted except in FIG. 2C, in the present disclosure, the metal member 40 is disposed on the base body 10 via the metal compound layer 60.

### Insulating Member

The insulating member 50 is a member that covers and insulates the metal member 40 such that the metal member 40 is not exposed from the second surface 10B. The insulating member 50 is disposed in the groove portion 14, and it is preferable that a surface of the insulating member 50 and the second surface 10B are flat surfaces in the same plane. The insulating member 50 preferably has a curved surface facing the curved surface CS of the groove portion 14. Accordingly, the distance between the metal member 40 and the second surface 10B along the interface between the insulating member 50 and the base body 10 can be increased, and the insulating property can be improved.

The material of the insulating member 50 can include or be a ceramic and/or a resin. The material of the insulating member 50 is preferably insulating and has high thermal conductivity, and is preferably, for example, at least one of cement or glass containing BN or the like, thermosetting resins, such as epoxy resin, silicone resin, phenol resin, polyimide resin, polyurethane resin, melamine resin, and urea resin, and thermoplastic resins, such as polyvinyl pyrrolidone resin, polyvinyl alcohol resin, polyethylene glycol resin, and polyamide resin, or the like, or combinations thereof.

In the wiring substrate 1 having the above-described configuration, one of the two wiring layers is embedded on the second surface 10B side and insulated by the insulating member 50, and the second surface 10B side is a flat surface. Accordingly, the wiring substrate 1 can be bonded to a heat dissipating plate or the like via a conductive bonding member, the thermal bonding property can be improved, and the heat dissipating property can be improved.

### Manufacturing Method of Wiring Substrate

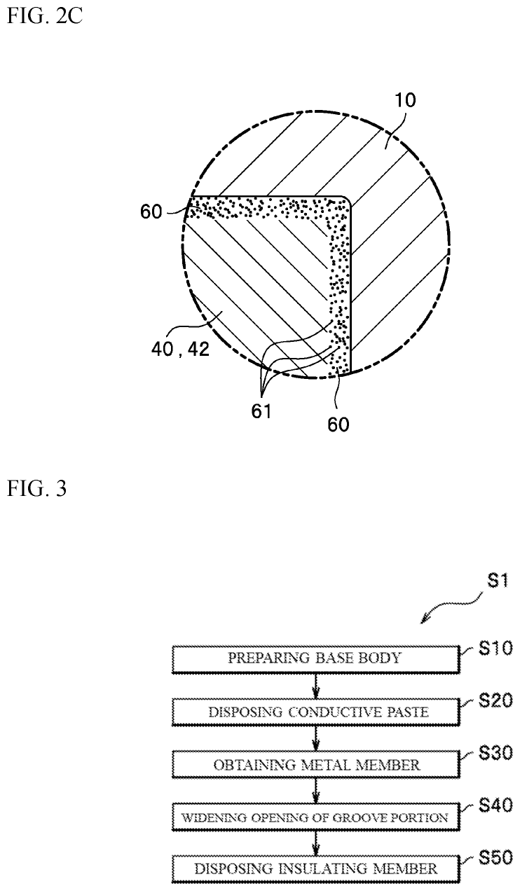

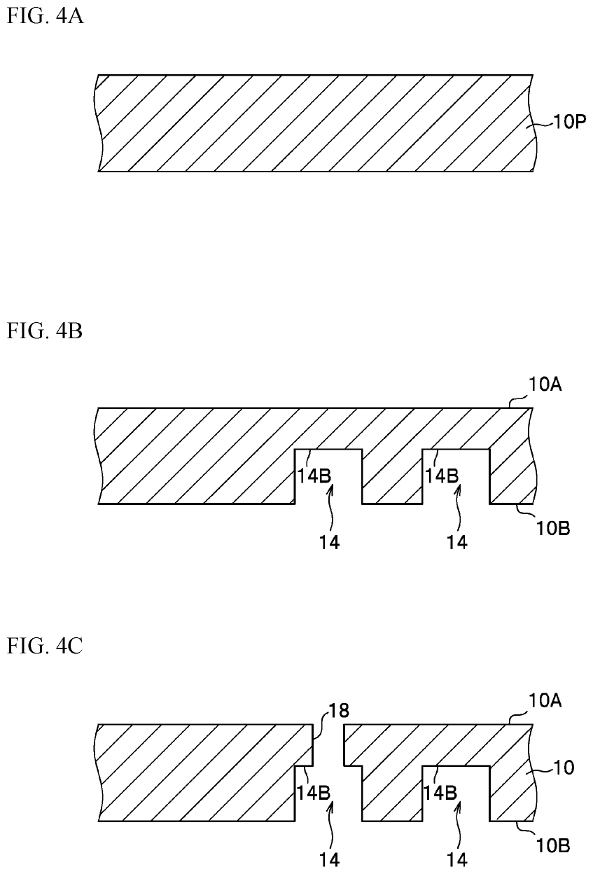

A manufacturing method S1 of the wiring substrate according to the embodiment will be described below with reference to the drawings. FIG. 3 is a flowchart for an example of the manufacturing method S1 of the wiring substrate. FIG. 4A is a schematic cross-sectional view of an example of the base body 10 before being processed. FIG. 4B is a schematic cross-sectional view of an example of the base body 10 in which the groove portions 14 have been formed. FIG. 4C is a schematic cross-sectional view of an example of the base body 10 in which the through hole 18 has been formed. FIG. 4D is a schematic cross-sectional view of an example of the base body 10 on which a conductive paste 80 has been disposed. FIG. 4E is a schematic cross-sectional view of an example of the base body 10 in which the conductive paste 80 has been fired. FIG. 4F is a schematic cross-sectional view of an example of the base body 10 in which the openings 14A of the groove portions 14 have been formed on the curved surfaces CS. FIG. 4G is a schematic cross-sectional view of an example of the base body 10 in which the insulating members 50 have been disposed in the groove portions 14. FIG. 4H is a schematic cross-sectional view of an example of the base body 10 in which the insulating members 50 have been polished.

The manufacturing method S1 of the wiring substrate includes: S10 of preparing the base body 10 having the first surface 10A and the second surface 10B as an opposite side to the first surface 10A, the base body 10 including the through holes 18 and the groove portions 14, the through holes 18 extending through so as to connect the first surface 10A and the second surface 10B, the groove portions 14 being connected to the through holes 18 and located on the second surface 10B; S20 of disposing the conductive paste 80 in the groove portions 14 and the through holes 18, the conductive paste 80 containing at least a metal powder, an active metal powder, and an organic solvent; S30 of obtaining the metal members 40 by firing the conductive paste 80; and S50 of disposing the insulating members 50 so as to close the openings 14A of the groove portions 14. In addition, here, the manufacturing method S1 of the wiring substrate further includes S40 of widening the openings 14A of the groove portions 14 after S30 of obtaining the metal members 40 and before S50 of disposing the insulating members 50.

That is, the manufacturing method S1 of the wiring substrate includes S10 of preparing the base body 10, S20 of disposing the conductive paste 80, S30 of obtaining the metal members 40, S40 of widening the openings 14A of the groove portions 14, and S50 of disposing the insulating members 50. Each configuration of the manufacturing method S1 of the wiring substrate is described below.

### Preparing Base Body

In S10 of preparing the base body (hereinafter referred to as a step S10), the base body 10 is prepared. The base body 10 has the first surface 10A and the second surface 10B as an opposite side to the first surface 10A, and includes the through holes 18 and the groove portions 14. The through holes 18 extend through so as to connect the first surface 10A and the second surface 10B, and the groove portions 14 are connected to the through holes 18 and located on the second surface 10B.

The base body 10 to be prepared is preferably a fired ceramic containing silicon nitride or aluminum nitride. The second surface 10B is preferably smoothed such that, for example, the arithmetic mean roughness Ra defined by the JIS B0601 is in a range from 0.01 μm to 1.5 μm. The smoothing can be performed by, for example, polishing. By the second surface 10B being smoothed, adhesion can be improved when the wiring substrate is bonded to an external heat dissipating plate or the like.

A fired ceramic substrate 10P is a plate-shaped member. The through hole 18 is formed to the depth of the bottom surface 14B of the groove portion 14, and the through hole 18 and the groove portion 14 can extend through the ceramic substrate 10P. Either the through hole 18 or the groove portion 14 may be formed first. Here, the through hole 18 is formed after the groove portion 14 is formed.

In the step S10, the groove portion 14 and the through hole 18 can be formed by laser processing. Here, the through hole 18 is formed so as to have the same diameter from the first surface 10A to the bottom surface 14B. By emitting a CO₂ laser from the first surface 10A side, for example, the through hole 18 can be formed such that it has a diameter decreasing from the first surface 10A toward the bottom surface 14B.

### Disposing Conductive Paste

In S20 of disposing the conductive paste (hereinafter referred to as a step S20), the conductive paste 80 containing at least a metal powder, an active metal powder, and an organic solvent is disposed in the groove portions 14 and the through holes 18. The conductive paste 80 is further disposed on the first surface 10A. Note that the conductive paste 80 is fired to form the metal members 40.

The metal powder is a powder that contains at least one of Cu, Cr, Ni, Ag, Al, Zn, Sn, and an Ag—Cu alloy. Among them, an Ag—Cu alloy that can be fired at a relatively low temperature, for example, in a range from 780° C. to 850° C. is preferable. Also, Cu or Ag is preferable since they have high electrical conductivity. Here, the metal powder contains, as a main component, an Ag—Cu alloy having a mixing ratio close to an Ag—Cu eutectic in which the mixing ratio of Ag and Cu is 72:28. The metal powder preferably has a median diameter in a range from 1 μm to 50 μm. In addition to an Ag—Cu alloy, a metal powder having a melting point higher than a melting point of the Ag—Cu alloy, for example, at least one of Cu, Cr, and Ni, may be contained. Accordingly, when the Ag—Cu alloy is fired at a temperature close to a range from 800° C. to 850° C., for example, the contained metal powder having a melting point higher than the firing temperature does not allow the metal powder to melt. Therefore, the volume shrinkage of the conductive paste 80 can be suppressed, and the thermal conductivity and the electrical conductivity of the conductive paste 80 can be increased.

The active metal powder is a powder containing an active metal element, and can be a powder containing at least one selected from TiH₂, CeH₂, ZrH₂, and MgH₂. Here, the active metal powder preferably contains TiH₂ so as to react with the nitrogen contained in the base body 10 prepared in the step S10.

The organic solvent is a solvent serving as a binder for the metal powder and the active metal powder, and can be, for example, a resin, such as acrylic, epoxy, urethane, ethyl cellulose, silicone, phenol, polyimide, polyurethane, melamine, or urea. The viscosity of the conductive paste 80 can be adjusted depending on the type and amount of the organic solvent.

As an example, the metal powder contained in the conductive paste 80 is in a range from 60% to 90% by weight, the active metal powder is in a range from 1% to 10% by weight, and the organic solvent is in a range from 5% to 30% by weight. Preferably, the metal powder is in a range from 70% to 85% by weight, and the active metal powder is in a range from 1% to 10% by weight. It is preferable that the total metal component of the metal powder and the active metal powder be 90% by weight or less, and the organic solvent of the conductive paste 80 disposed in the groove portion 14 be 10% by weight or more. By increasing the content ratio of the organic solvent, it is possible to increase the volume shrinkage rate accompanying drying at the time of firing, and it is possible to recess a surface of the metal member 40 after firing the conductive paste 80.

The conductive paste 80 can be disposed by screen printing, for example. A conductive paste 80A disposed on the first surface 10A side may be the same as a conductive paste 80B disposed on the second surface 10B side, but is preferably different therefrom. The conductive paste 80A disposed on the first surface 10A side preferably has a lower content ratio of the organic solvent than the conductive paste 80B disposed on the second surface 10B side, and preferably has a smaller volume shrinkage rate accompanying drying at the time of firing. The conductive paste 80A disposed on the first surface 10A is preferably disposed so as to have a uniform thickness from the first surface 10A.

### Obtaining Metal Member

In S30 of obtaining the metal members (hereinafter referred to as a step S30), the conductive paste 80 is fired to obtain the metal members 40. The firing temperature can be in a range from 780° C. to 1100° C., and is preferably in a range from 780° C. to 850° C. The firing atmosphere is preferably a vacuum atmosphere of 10-5 Pa or less or an Ar atmosphere of 99.9% or more.

The conductive paste 80 disposed in the groove portion 14 becomes the embedded wiring line 42 of the metal member 40, the conductive paste 80 disposed in the through hole 18 becomes the via wiring line 43, and the conductive paste 80 disposed on the first surface 10A becomes the exposed wiring line 41, the pad portion 45, and the terminal portion 46.

By firing the conductive paste 80, the organic solvent is decomposed, volatilized, and removed. By the organic solvent being removed, the volume of the metal member 40 shrinks with respect to the volume of the conductive paste 80. Due to this shrinkage, the metal member 40 is disposed on the bottom surface 14B side of the groove portion 14 and in the through hole 18 away from the opening 14A of the groove portion 14. That is, in the groove portion 14, the metal member 40 is disposed closer to the bottom surface 14B side, which allows the insulating property on the second surface 10B side to be improved. In addition, due to this shrinkage, the surface of the metal member 40 on the second surface 10B side is curved so as to be recessed toward the first surface 10A side. That is, the metal member 40 is formed such that the surface thereof on the second surface 10B side is a curved surface.

In addition, a metal compound layer containing a reaction product of a non-metal element contained in the base body 10 and the active metal element contained in the metal member 40 is formed by the firing. That is, the metal member 40 includes a metal compound layer changed from the active metal powder at the interface between the base body 10 and the metal member 40. Here, the metal compound layer contains TiN, which is a reaction product of nitrogen contained in the base body 10 and TiH₂ contained in the active metal powder of the conductive paste 80. Providing the metal compound layer at the interface between the base body 10 and the metal member 40 allows improving the reliability of bonding.

### Widening Opening of Groove Portion

In S40 of widening the openings of the groove portions (hereinafter referred to as a step S40), the opening 14A of the groove portion 14 is formed so as to be widened by removing a part of each of the base body 10 and the metal member 40 such that the groove portion 14 is continuous with the second surface 10B via the curved surface CS widening toward the opening 14A side. Here, a part of each of the base body 10 and the metal member 40 is removed by blasting processing. The blasting processing allows removing the end portion of the metal member 40 on the opening 14A side and removing the corner portion of the base body 10 in the opening 14A to form the curved surface CS having roundness.

The curved surface CS can be formed in, for example, an arc shape in the widthwise cross section. The metal member 40 is disposed closer to the bottom surface 14B side than the curved surface CS. The step S40 may be performed by polishing with a ceramic fiber brush, etching, laser processing, or the like.

### Disposing Insulating Member

In S50 of disposing the insulating members (hereinafter referred to as a step S50), the insulating members 50 are disposed so as to close the openings 14A of the groove portions 14. The metal member 40 exposed on the second surface 10B side is covered with the insulating member 50 that is insulating, and the metal member 40 is insulated with respect to the second surface 10B side.

It is preferable that the insulating member 50 be disposed in the groove portion 14 having a width wider than a width of the metal member 40. In the step S40, the width W1 of the opening 14A of the groove portion 14 is formed wider than the width W2 of the bottom surface 14B. Therefore, the insulating member 50 can be disposed so as to have a wider width on the opening 14A side than on the bottom surface 14B side. Accordingly, the insulating property can be improved.

The insulating member 50 can be disposed by, for example, applying an unhardened or undried material of the insulating member 50, and solidifying the material by heating or the like. The material of the insulating member 50 can be a ceramic cement containing BN or the like, a resin, such as epoxy resin or silicone resin, glass, or the like. The insulating member 50 can be disposed by potting, spraying, ink jetting, screen printing, or the like.

The insulating member 50 is preferably disposed so as to form a flat surface in the same plane with the second surface 10B. Here, the insulating member 50 is solidified or hardened so as to protrude from the second surface 10B, and the protruding insulating member 50 is polished such that the second surface 10B and the insulating member 50 form a flat surface in the same plane. Since the insulating member 50 and the second surface 10B form a flat surface, the wiring substrate 1 and an external heat dissipating plate or the like can be brought into close contact with each other to suppress generation of an air layer, thus improving a thermal transfer efficiency.

The area of the insulating member 50 on the second surface side of the wiring substrate 1 is preferably as small as possible. By reducing the area of the insulating member 50, it is possible to increase the area in which the base body 10 having a high thermal conductivity faces an external heat dissipating plate or the like, thus allowing the heat dissipating property to be improved.

In the manufacturing method S1 of the wiring substrate including the above-described configuration, the metal member 40 is disposed on the bottom surface 14B side of the groove portion 14 provided on the second surface 10B of the base body 10, and the insulating member 50 is disposed so as to close the groove portion 14. Thus, a wiring line insulated from the second surface 10B side can be provided without stacking a sheet or the like as a material of the base body. In addition, the insulating property can be improved by removing a part of each of the base body 10 and the metal member 40 and widening the opening 14A to be formed as a curved surface.

In the step S10, the groove portion 14 may be formed by blasting processing, and the through hole 18 may be formed by laser processing. By forming the groove portion 14 by blasting processing, the bottom surface 14B can be formed in a curved shape that becomes deeper on the center side of the groove portion 14. Accordingly, the area in which the metal member 40 and the base body 10 face each other can be increased, which allows the heat dissipating property and the bonding property to be further improved. Also, the groove portion 14 and the through hole 18 may be formed by blasting processing, punching, etching, or the like.

### Modified Example of Wiring Substrate

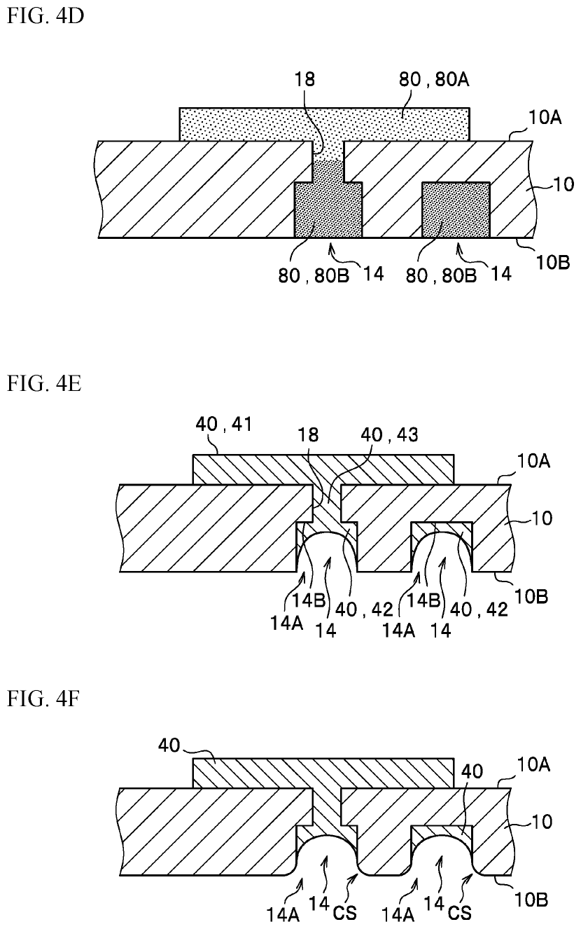

A modified example of the wiring substrate will be described below. FIG. 5A is a schematic cross-sectional view of an example of a wiring substrate 1A of the modified example.

The wiring substrate 1A of the modified example is different from the wiring substrate 1 in that the base body 10 includes recessed portions 16 on the first surface 10A and includes the through holes 18 at positions of the recessed portions 16. In the wiring substrate 1A of the modified example, the metal member 40 is disposed not on the first surface 10A but in the recessed portion 16. By disposing the metal member 40 in the recessed portion 16, the thickness of the wiring substrate can be reduced. In addition, it is preferable that the metal member 40 disposed in the recessed portion 16 and the first surface 10A of the base body 10 form a flat surface in the same plane. Accordingly, it is possible to further reduce the thickness of the wiring substrate.

In the wiring substrate 1A of the modified example, the pad portion 45, the terminal portion 46, and the exposed wiring line 41 are disposed on the recessed portion 16. The depth of the recessed portion 16 from the first surface 10A can be, for example, in a range from 5 μm to 100 μm, and is preferably in a range from 10 μm to 50 μm.

### Manufacturing Method of Modified Example of Wiring Substrate

A manufacturing method of the modified example of the wiring substrate will be described below. FIG. 5B is a schematic cross-sectional view of an example of the base body 10 in which the conductive paste 80 has been fired in the manufacturing method of the wiring substrate 1A of the modified example.

The manufacturing method of the wiring substrate 1A of the modified example is different from the manufacturing method S1 in that the base body to be prepared includes the recessed portions 16 on the first surface 10A and the conductive paste 80 is disposed not on the first surface 10A but in the recessed portions 16. In addition, the metal members 40 on the first surface 10A side being polished is included.

In the manufacturing method of the wiring substrate 1A of the modified example, in S10 of preparing the base body, the first surface 10A further includes the recessed portions 16, and includes the through holes 18 at the positions of the recessed portions 16. The recessed portion 16 is formed in a region of the first surface 10A in which the exposed wiring line 41, the pad portion 45, and the terminal portion 46 are to be provided. The depth of the recessed portion 16 can be, for example, in a range from 5 μm to 100 μm, and is preferably in a range from 10 μm to 50 μm. The recessed portion 16 can be formed by etching, blasting processing, or laser processing. Either the formation of the through hole 18 or the formation of the recessed portion 16 may be performed first.

In S20 of disposing the conductive paste, the conductive paste 80 is disposed in the recessed portion 16 formed together with the groove portion 14 and the through hole 18. The step S30 can be performed in a manner similar to that of the manufacturing method S1.

The manufacturing method of the wiring substrate 1A of the modified example further includes, after the step S30, polishing the metal members 40 such that the first surface 10A of the base body 10 and the metal members 40 form a flat surface in the same plane. The polishing of the metal members may be performed at any stage after the step S30. Here, the step S40 and the step S50 are performed first. The polishing can be performed with aluminum oxide, diamond, silicon carbide, or the like. The step S40 and the step S50 can be performed in a manner similar to that of the manufacturing method S1.

### Application Example of Wiring Substrate

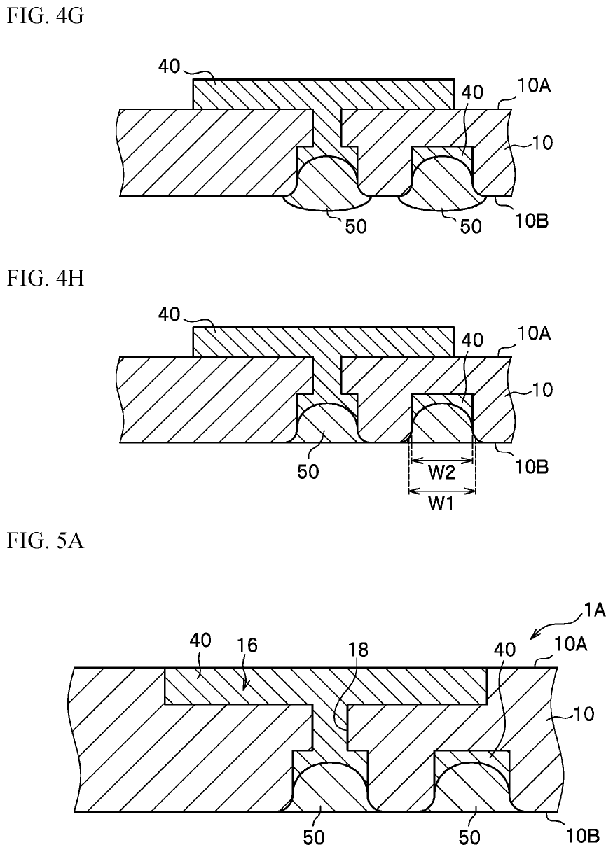

An application example of the wiring substrate will be described below. FIG. 6 is a schematic cross-sectional view of the application example of the wiring substrate.

The application example of the wiring substrate is a device in which a heat dissipating plate 90 is bonded to the second surface 10B side of the wiring substrate 1 via a bonding member 95. The surface of the heat dissipating plate 90 bonded to the second surface 10B side is a flat surface. Here, the heat dissipating plate 90 is a plate-shaped member. The heat dissipating plate 90 may be provided with protrusions and recesses on a surface other than the surface bonded to the wiring substrate 1 so as to increase the surface area, for example. The material of the heat dissipating plate 90 can be a metal, such as copper or aluminum.

The bonding member 95 is a member that bonds or adheres the wiring substrate 1 to the heat dissipating plate 90. Since the bonding member 95 fills the gap between the wiring substrate 1 and the heat dissipating plate 90, air is expelled and the thermal transfer efficiency can be improved. In the wiring substrate 1, since the second surface 10B side is insulated, it is possible to use the conductive bonding member 95 obtained by hardening a solder, a brazing material, a paste containing Ag, or the like, and the heat dissipating property can be improved.

Note that, in the application example of the wiring substrate, the wiring substrate 1A of the modified example can be used instead of the wiring substrate 1. In the wiring substrate 1A of the modified example, the second surface 10B side has a configuration similar to that of the wiring substrate 1, and the heat dissipating plate 90 is bonded via the bonding member 95 in a manner similar to that of the wiring substrate 1, and thus the heat dissipating property can be improved.

### Light-Emitting Device

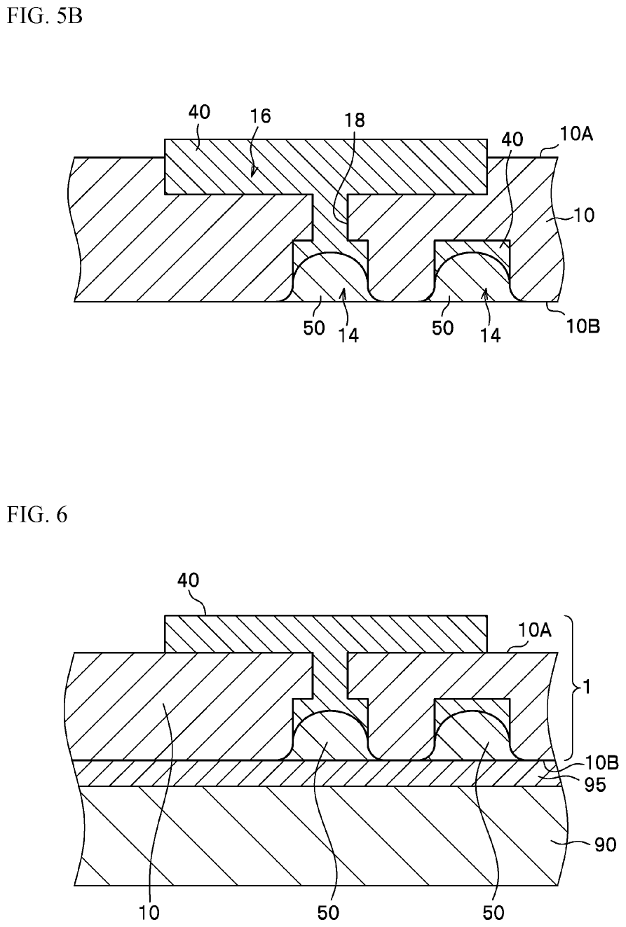

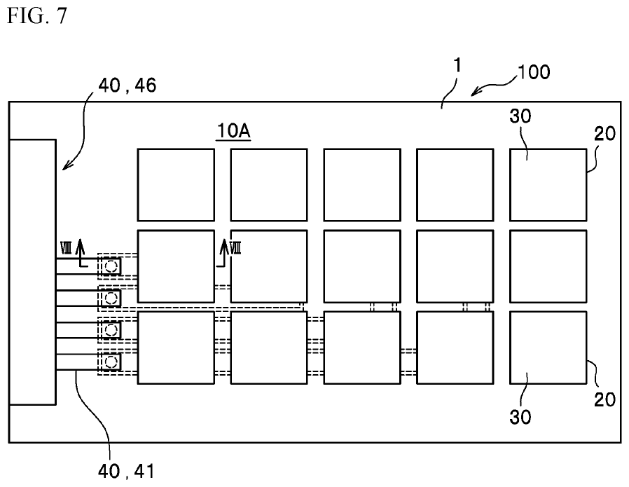

A light-emitting device 100 according to the embodiment will be described below with reference to the drawings. FIG. 7 is a plan view of an example of the light-emitting device 100. FIG. 8 is a schematic cross-sectional view taken along a line VIII-VIII in FIG. 7.

The light-emitting device 100 is a device in which the application example of the wiring substrate and light-emitting elements 20 are combined, and it is possible to control turning on/off and brightness of each light-emitting element 20 from the outside via the terminal portion 46. Here, fifteen light-emitting elements 20 are disposed in line on the first surface 10A side. The number of light-emitting elements 20 is not particularly limited.

The light-emitting device 100 includes the wiring substrate 1 and the light-emitting elements 20 disposed on the first surface 10A side of the wiring substrate 1. The light-emitting elements 20 include element electrodes 21. The metal members 40 of the wiring substrate 1 are electrically connected to the element electrodes 21. Here, a light-transmissive member 30 is disposed on the upper surface of the light-emitting element 20. Each component of the light-emitting device 100 is described below.

### Wiring Substrate

On the wiring substrate 1, the light-emitting element 20 is disposed with the first surface 10A side as the upper surface. The pad portion 45 of the metal member 40 has a size and a shape that allow the element electrode 21 of the light-emitting element 20 to be disposed. In the wiring substrate 1, the heat dissipating plate 90 is bonded to the second surface 10B side via the bonding member 95 as in the application example of the wiring substrate described above.

### Light-Emitting Element

The light-emitting element 20 is a member that is supplied with power and emits light. The light-emitting element 20 has, for example, a rectangular shape. The light-emitting element 20 includes a semiconductor layered body, and here, a light-transmissive substrate of sapphire, gallium nitride, or the like is disposed on the upper surface side of the semiconductor layered body, and is provided with a pair of the element electrodes 21 on the lower surface side. For the semiconductor layered body, an arbitrary composition can be used in accordance with a desired emission wavelength, and for example, it is possible to use a nitride semiconductor (InₓAl_{y}Ga_{1-x-y}N, 0≤ X, 0≤ Y, X+Y≤1) or GaP, which can emit blue or green light, or GaAlAs or AlInGaP, which can emit red light. The size and the shape of the light-emitting element 20 can be appropriately selected in accordance with the purpose of use.

The pair of element electrodes 21 have a rectangular shape as an example, and are exposed on the lower surface of the light-emitting element 20. The element electrode 21 can be formed of, for example, a single-layer film or a layered film of a metal such as gold, platinum, palladium, rhodium, nickel, tungsten, molybdenum, chromium, or titanium, or an alloy thereof.

Here, the element electrode 21 is electrically connected to the pad portion 45 of the metal member 40 via a conductive member 70. The conductive member 70 can be made of, for example, a metal, such as gold or solder, or a hardened conductive paste material, which is a mixture of a powdered metal and a resin binder.

### Light-Transmissive Member

The light-transmissive member 30 is a member that protects the upper surface of the light-emitting element 20 and is positioned on a light extraction surface of the light-emitting device 100. Here, the light-transmissive member 30 has a rectangular shape as an example, and has the same size and the same shape as those of the light-emitting element 20 in a plan view. The light-transmissive member 30 may have a shape and a size that include the light-emitting element 20 in a plan view.

The light-transmissive member 30 is made of, for example, a light-transmissive resin material, and an epoxy resin, a silicone resin, a resin in which these resins are mixed, or the like can be used. The light-transmissive member 30 may contain a phosphor, and for example, when the light-transmissive member 30 contains a phosphor that absorbs blue light from the light-emitting element 20 and emits yellow light, white light can be emitted from the light-emitting device 100. The light-transmissive member 30 may contain a plurality of types of phosphors, and for example, when the light-transmissive member 30 contains a phosphor that absorbs blue light from the light-emitting element 20 and emits green light and a phosphor that emits red light, white light can also be emitted from the light-emitting device 100.

The light-transmissive member 30 may further contain a light-emitting material such as a phosphor or a quantum dot. Examples of such a phosphor include yttrium-aluminum (gallium-doped) garnet activated with cerium, nitrogen-containing calcium (strontium) aluminosilicate activated with europium, potassium fluorosilicate activated with manganese, and a β-SiAlON phosphor. Specific examples of the phosphor include an yttrium aluminum garnet phosphor (for example, (Y,Gd)₃(Al,Ga)₅O₁₂:Ce), a lutetium aluminum garnet phosphor (for example, Lu₃(Al,Ga)₅O₁₂:Ce), a terbium aluminum garnet phosphor (for example, Tb₃(Al,Ga)₅O₁₂:Ce), a CCA phosphor (for example, Ca₁₀(PO₄)₆Cl₂:Eu), an SAE phosphor (for example, Sr₄Al₁₄O₂₅:Eu), a chlorosilicate phosphor (for example, Ca₈MgSi₄O₁₆Cl₂:Eu), a silicate phosphor (for example, (Ba,Sr,Ca,Mg)₂SiO₄:Eu), oxynitride phosphors such as a β-SiAlON phosphor (for example, (Si,Al)₃(O,N)₄:Eu) and an α-SiAlON phosphor (for example, Ca(Si,Al)₁₂(O,N)₁₆:Eu), nitride phosphors such as an LSN phosphor (for example, (La,Y)₃Si₆N₁₁:Ce), a BSESN phosphor (for example, (Ba,Sr)₂Si₅N₈:Eu), an SLA phosphor (for example, SrLiAl₃N₄:Eu), a CASN phosphor (for example, CaAlSiN₃:Eu), and an SCASN phosphor (for example, (Sr,Ca)AlSiN₃:Eu), fluoride phosphors such as a KSF phosphor (for example, K₂SiF₆:Mn), a KSAF phosphor (for example, K₂(Si₁₋ₓAlₓ)F₆₋ₓ:Mn, where x satisfies 0<x<1), and an MGF phosphor (for example, 3.5MgO·0.5MgF₂·GeO₂:Mn), and the like. Examples of the quantum dots include quantum dots having a perovskite structure (for example, (Cs,FA,MA)(Pb,Sn)(F,Cl,Br,I)₃, where FA represents formamidinium and MA represents methylammonium), II-VI group quantum dots (for example, CdSe), III-V group quantum dots (for example, InP), quantum dots having a chalcopyrite structure (for example, (Ag,Cu)(In,Ga)(S,Se)₂), and the like.

The light-emitting device 100 may include a covering member that covers lateral surfaces of the light-emitting element 20 and the light-transmissive member 30 on the upper surface of the wiring substrate 1. The covering member is a member that protects the upper surface of the wiring substrate 1, the light-emitting element 20, and the light-transmissive member 30, and is disposed with the upper surface of the light-transmissive member 30 being exposed.

The covering member can be formed of a resin having light reflectivity, light transmissivity, a light blocking property, or the like, any of these resins containing a light reflective substance, or the like. The covering member preferably has at least any of light reflectivity and a light blocking property. Examples of the resin include a resin containing one or more of a silicone resin, a modified silicone resin, an epoxy resin, a modified epoxy resin, and an acrylic resin, and a hybrid resin. Examples of the light reflective substance include titanium oxide, silicon oxide, zirconium oxide, potassium titanate, aluminum oxide, aluminum nitride, boron nitride, and mullite. The covering member may contain a phosphor, a diffusing material, a colorant, and the like.

The light-emitting device 100 having the above-described configuration includes the wiring substrate 1 in which the light-emitting elements 20 are disposed on the upper surface and the heat dissipating plate 90 is bonded to the lower surface. One of the element electrodes 21 is connected to the embedded wiring line 42 from the pad portion 45 on the upper surface through the via wiring line 43, returns to the upper surface through another via wiring line 43, and is connected to the exposed wiring line 41 extending toward the terminal portion 46. Accordingly, in the light-emitting device 100, the terminal portion 46 connected to an external wiring line can be disposed on the first surface 10A, thus increasing flexibility in the arrangement of the light-emitting elements 20. The lower surface of the wiring substrate 1 is insulated from the embedded wiring line 42 and is formed to be flat, and can be bonded to the flat surface of the heat dissipating plate 90 by the conductive bonding member 95. Accordingly, in the light-emitting device 100, the thermal bonding property between the wiring substrate 1 and the heat dissipating plate 90 can be improved, thus allowing the heat dissipating property to be improved.

### Manufacturing Method of Light-Emitting Device

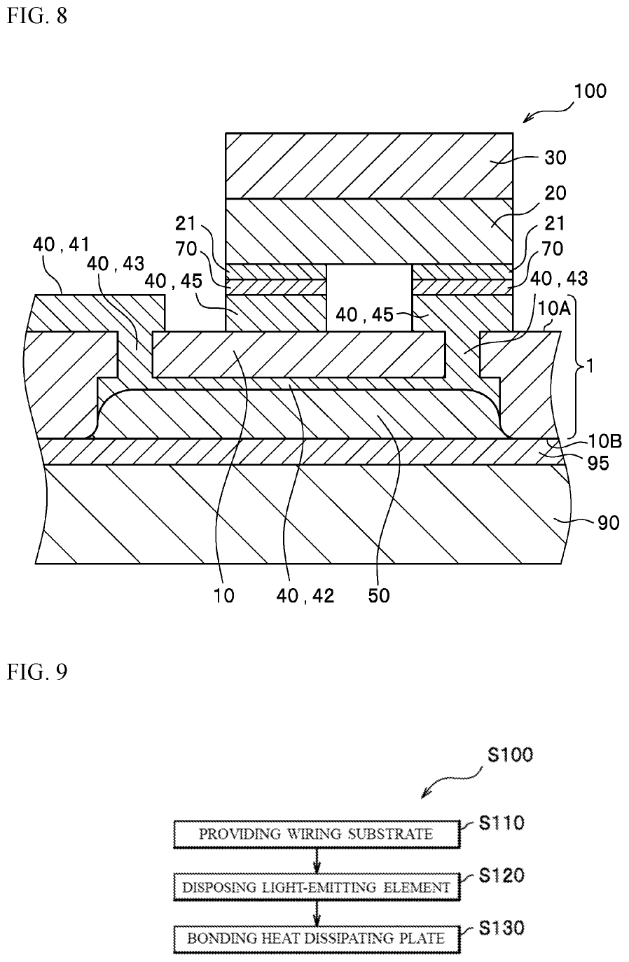

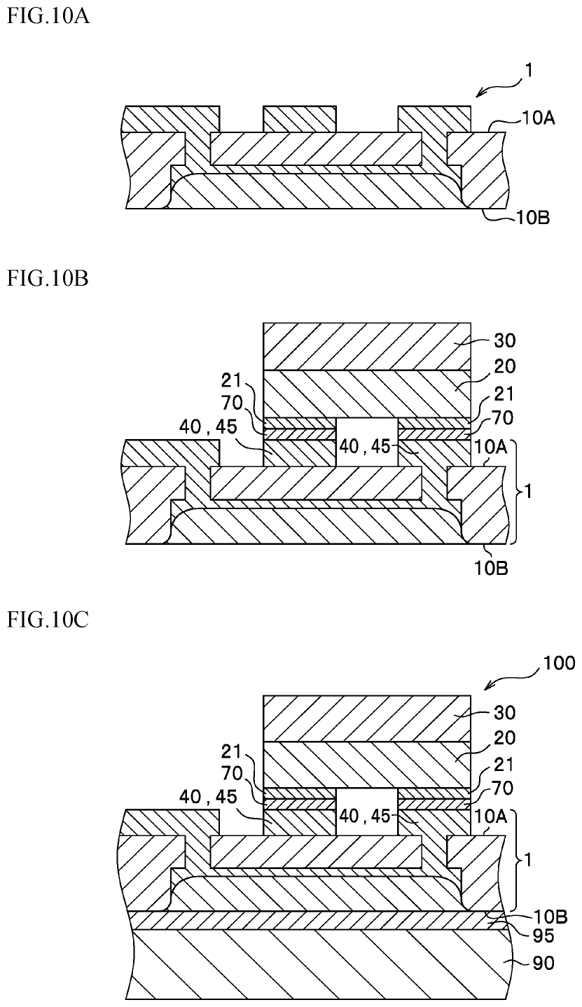

A manufacturing method S100 of the light-emitting device according to the embodiment will be described below with reference to the drawings. FIG. 9 is a flowchart exemplifying the manufacturing method S100 of the light-emitting device. FIG. 10A is a schematic cross-sectional view of an example of the prepared wiring substrate 1. FIG. 10B is a schematic cross-sectional view of an example of a state in which the light-emitting element 20 has been disposed on the wiring substrate 1. FIG. 10C is a schematic cross-sectional view of an example of a state in which the heat dissipating plate 90 has been bonded to the wiring substrate 1.

The manufacturing method S100 of the light-emitting device includes S110 of preparing the wiring substrate manufactured by the manufacturing method S1 of the wiring substrate, and S120 of disposing the light-emitting elements on the wiring substrate. In S120 of disposing the light-emitting elements on the wiring substrate, the metal member 40 of the wiring substrate 1 and the element electrode 21 are electrically connected. Here, after S120 of disposing the light-emitting elements, S130 of bonding the heat dissipating plate 90 is further included. Each configuration of the manufacturing method S100 of the light-emitting device is described below.

### Preparing Wiring Substrate

In S110 of preparing the wiring substrate (hereinafter, referred to as a step S110), the wiring substrate 1 manufactured by the manufacturing method S1 of the wiring substrate is prepared. In the wiring substrate 1, the first surface 10A side on which the light-emitting elements 20 are disposed is the upper surface, and the pad portions 45 of the metal members 40 are formed in accordance with the size and arrangement of the light-emitting elements 20, the interval between the pair of element electrodes 21, and the like.

### Disposing Light-Emitting Element

In S120 of disposing the light-emitting elements (hereinafter, referred to as a step S120), the light-emitting elements 20 are disposed with the element electrodes 21 on the wiring substrate 1 side. The light-emitting elements 20 can be aligned and disposed in the row direction and the column direction on the wiring substrate 1. The element electrode 21 is fixed to and electrically connected to the pad portion 45 of the metal member 40 by the conductive member 70. The connection by the conductive member 70 may be performed by disposing a bump of gold, solder, or the like on the element electrode 21 or the pad portion 45 and applying pressure and heat, or may be hardened by applying a conductive paste material.

The light-transmissive member 30 is disposed in advance on the upper surface of the light-emitting element 20. The light-transmissive member 30 can be disposed by applying the unhardened material of the light-transmissive member 30 by, for example, potting, spraying, inkjetting, printing, or the like, and then hardening the material. As the light-transmissive member 30, a member formed in a sheet form or a plate shape may be disposed on the upper surface of the light-emitting element 20 via a light-transmissive adhesive or the like, or the light-transmissive member 30 may be disposed on the upper surface of the light-emitting element 20 after the light-emitting element 20 on which the light-transmissive member 30 is not disposed in advance is disposed on the wiring substrate 1.

### Bonding Heat Dissipating Plate

In S130 of bonding the heat dissipating plate (hereinafter referred to as a step S130), the heat dissipating plate 90 is bonded to the second surface 10B side of the wiring substrate 1 on which the light-emitting elements 20 have been disposed via the bonding member 95. The heat dissipating plate 90 preferably has a flat surface to be bonded to the wiring substrate 1.

The step S130 can be performed by applying an unhardened bonding member 95, such as a solder paste, a brazing material, or a paste containing powdered Ag, to one or both of the wiring substrate 1 and the heat dissipating plate 90, and heating them while applying pressure thereto. Since the second surface 10B side of the wiring substrate 1 is insulated, the conductive bonding member 95 can be used.

The manufacturing method S100 of the light-emitting device may further include disposing a covering member after the step S120 and before or after the step S130. The covering member can be disposed, for example, by causing an unhardened resin material to be discharged from a dispenser nozzle to be applied, and then be hardened. The upper surface of the covering member is preferably formed so as to be in the same plane with the upper surface of the light-transmissive member 30. In disposing the covering member, the covering member may be further polished, or the covering member and the light-transmissive member 30 may be polished.

In the manufacturing method S100 of the light-emitting device having the above-described configuration, the light-emitting device 100 having a high heat dissipating property can be manufactured by disposing the light-emitting elements 20 on the wiring substrate 1 having an improved thermal bonding property with the heat dissipating plate 90.

What is claimed is:

1. A wiring substrate, comprising:
a base body that is insulating and has a first surface and a second surface on an opposite side to the first surface, the base body including a groove portion provided on a second surface side and a through hole connecting the first surface and a bottom surface of the groove portion;
a metal member disposed in the groove portion on a bottom surface side of the groove portion and in the through hole away from an opening of the groove portion; and
an insulating member disposed so as to close the opening of the groove portion.

2. The wiring substrate according to claim 1, wherein
the insulating member is disposed in the groove portion, and a surface of the insulating member and the second surface are flat surfaces in the same plane.

3. The wiring substrate according to claim 1, wherein
the metal member disposed in the groove portion has a curved surface.

4. The wiring substrate according to claim 1, wherein
the groove portion is continuous with the second surface via a curved surface widening toward an opening side, and
the insulating member is disposed in the groove portion having a width greater than a width of the metal member.

5. The wiring substrate according to claim 1, wherein
the base body includes a recessed portion on the first surface, and includes the through hole at a position of the recessed portion.

6. The wiring substrate according to claim 1, wherein
the wiring substrate includes a pad portion and a terminal portion on a first surface side, the pad portion is disposed at a position to which a circuit component is connected, and the terminal portion is disposed at a position to which an external wiring line is connected, and
the pad portion and the terminal portion are electrically connected to the metal member disposed in the through hole.

7. The wiring substrate according to claim 1, wherein
a material of the insulating member includes a ceramic and/or a resin.

8. The wiring substrate according to claim 1, wherein
a material of the base body includes a ceramic.

9. The wiring substrate according to claim 1, wherein
the base body contains at least one of silicon nitride, aluminum nitride, boron nitride, magnesium oxide, or aluminum oxide.

10. The wiring substrate according to claim 1, wherein
the metal member contains at least one of Cu, Cr, Ni, Ag, Al, Zn, Sn, or an Ag—Cu alloy.

11. The wiring substrate according to claim 1, wherein
the metal member includes a metal compound layer at an interface between the base body and the metal member.

12. A light-emitting device, comprising:
the wiring substrate according to claim 1; and
a light-emitting element disposed on a first surface side of the wiring substrate, the light-emitting element including an element electrode, wherein
the metal member of the wiring substrate is electrically connected to the element electrode.

13. A manufacturing method of a wiring substrate, comprising:
preparing a base body having a first surface and a second surface on an opposite side to the first surface, the base body including a through hole and a groove portion, the through hole extending through so as to connect the first surface and the second surface, the groove portion being connected to the through hole and located at a second surface side;
disposing a conductive paste in the groove portion and the through hole, the conductive paste containing at least a metal powder, an active metal powder, and an organic solvent;
obtaining a metal member by firing the conductive paste; and
disposing an insulating member so as to close an opening of the groove portion.

14. The manufacturing method of the wiring substrate according to claim 13, wherein
in the disposing the conductive paste, the metal powder contained in the conductive paste is in a range from 60% to 90% by weight, the active metal powder is in a range from 1% to 10% by weight, and the organic solvent is in a range from 5% to 30% by weight.

15. The manufacturing method of the wiring substrate according to claim 13, wherein
in the obtaining the metal member, the metal member is disposed on a bottom surface side of the groove portion and in the through hole away from the opening of the groove portion.

16. The manufacturing method of the wiring substrate according to claim 13, wherein
in the obtaining the metal member, the metal member is formed so as to have a curved surface.

17. The manufacturing method of the wiring substrate according to claim 13, further comprising
after the obtaining the metal member, removing a part of each of the base body and the metal member to widen the opening of the groove portion such that the groove portion is continuous with the second surface via a curved surface widening toward an opening side, wherein
in the disposing the insulating member, the insulating member is disposed in the groove portion having a width greater than a width of the metal member.

18. The manufacturing method of the wiring substrate according to claim 17, wherein
in the widening the opening of the groove portion, a part of each of the base body and the metal member is removed by blasting processing.

19. The manufacturing method of the wiring substrate according to claim 13, wherein
in the obtaining the metal member, a metal compound layer changed from the active metal powder is provided at an interface between the base body and the metal member.

20. The manufacturing method of the wiring substrate according to claim 13, wherein
in the preparing the base body, the first surface further includes a recessed portion, and the base body includes the through hole at a position of the recessed portion.

21. The manufacturing method of the wiring substrate according to claim 13, wherein
in the preparing the base body, the groove portion and the through hole are formed by laser processing.

22. The manufacturing method of the wiring substrate according to claim 13, wherein
in the preparing the base body, the groove portion is formed by blasting processing, and the through hole is formed by laser processing.

23. The manufacturing method of the wiring substrate according to claim 13, wherein
in the obtaining the metal member, a firing temperature is in a range of 780° C. to 1100° C.

24. The manufacturing method of the wiring substrate according to claim 13, wherein
in the obtaining the metal member, a firing atmosphere is a vacuum atmosphere of 10-5 Pa or less or an atmosphere containing 99.9% or more Ar.

25. The manufacturing method of the wiring substrate according to claim 20, further comprising
after the obtaining the metal member, polishing the metal member such that the first surface of the base body and the metal member form a flat surface in the same plane.

26. A manufacturing method of a light-emitting device, comprising:
providing the wiring substrate manufactured by the manufacturing method of the wiring substrate according to claim 13; and
disposing a light-emitting element on the wiring substrate, the light-emitting element including an element electrode, wherein
in the disposing the light-emitting element, the metal member of the wiring substrate and the element electrode are electrically connected.

27. The wiring substrate according to claim 1, wherein
a material of the insulating member is a ceramic or a resin.

28. The wiring substrate according to claim 1, wherein
a material of the base body is a ceramic.
